(19) United States
(12) Patent Application Publication
(10) Pub. No.: US 2024/0369604 A1
(43) Pub. Date: Nov. 7, 2024

(54) SMART PLANT MONITORING POWER CONNECTOR AND METHOD FOR CONTROLLING PLANT MONITORING

(71) Applicant: LG-LED SOLUTIONS LIMITED, Shenzhen, Guangdong (CN)

(72) Inventor: Dongwen Wu, Shenzhen (CN)

(21) Appl. No.: 18/140,355

(22) PCT Filed: Sep. 7, 2022
(86) PCT No.: PCT/CN2022/117475

§ 371 Date: Apr. 27, 2023

(30) Foreign Application Priority Data
Aug. 15, 2022 (CN) 202210975627.3

(51) Int. Cl. G01R 19/175; G01R 21/06

(52) U.S. Cl. CPC G01R 19/175; G01D 21/02; G01R 21/06; H01R 13/6691

(57) ABSTRACT

The present invention belongs to the technical field of control for plant monitoring, and particularly relates to a smart plant monitoring power connector and a method for controlling plant monitoring. The smart plant monitoring power connector comprises an power connector, and further comprises: a sensor interface circuit, a sensor interface circuit and a communication control circuit, wherein the communication control circuit is used for acquiring, via the sensor interface circuit, current environment information monitored by the environment monitoring device; the communication control circuit is further used for performing information interaction with an intelligent communication terminal so as to send the acquired current environment information to the intelligent communication terminal. The present invention achieves that the smart plant monitoring power connector is used as a master control device for the first time; since power supply is essential in the plant monitoring process, by combining the power supply and control, there is no need to separately set the power supply, the convenience in the plant growth monitoring process is greatly improved, so as to meet the user's use requirements, which improves the plant monitoring efficiency.

### FIELD OF THE INVENTION

The present invention belongs to the technical field of control for plant monitoring, and particularly relates to a smart plant monitoring power connector and a method for controlling plant monitoring.

### BACKGROUND OF THE INVENTION

At present, in the market, multiple monitoring devices are generally used for monitoring plant growth, and each monitoring device uses a power connector for power supply, wherein there are various types of monitoring devices, for example, devices for carrying out illumination monitoring include an electronic ornament and a vase thereof, an electronic plant, and a system for managing illumination and a method for supplementing illumination as disclosed in the invention patent application NO. CN110730547A, wherein the system for managing illumination comprises a processing unit, a monitoring unit and a light supplementing unit, wherein the monitoring unit is used for acquiring information on the plant species and information on the illumination of plants, and the monitoring unit is communicatively connected to the processing unit.

The technical solution disclosed in the above patent document, although capable of being controllably connected to the processing unit and capable of executing a light supplementation strategy for supplementing illumination for the plant, is only capable of monitoring and controlling illumination during plant growth due to the single function thereof; if other parameters of plant growth need to be monitored, adjusted and controlled, other monitoring devices need to be disposed separately; for example, it is necessary to combine an intelligent control watering device for bionic remediation of polluted soil by plants as disclosed in the invention patent application No. CN106212212A for monitoring soil. In this way, when a variety of monitoring devices are used in combination, there are great defects, which firstly leads to a great increase in the production costs; secondly, because each monitoring device has its own separate control part, the user needs to use different monitoring devices respectively, which further results in great inconvenience in the process of use and easily causes the problem that the efficiency of plant monitoring is affected. Furthermore, if manual control is required, each monitoring device needs to be adjusted and controlled separately, which results in inconvenience in adjustment and control. In addition, when power is supplied to different monitoring devices, a separate power connector needs to be used for power supply. However, current power connectors on the market have a single function, and most of them only have a power supply function and cannot be used in intelligent cooperation with various monitoring devices, which leads to the problem that due to the single function of the extension power connector, the use in plant monitoring is affected, thus affecting the efficiency of plant monitoring.

Thus, it is necessary to design a smart plant monitoring power connector and a method for controlling plant monitoring.

### SUMMARY OF THE INVENTION

The present invention aims to provide a smart plant monitoring power connector and a method for controlling plant monitoring so as to solve the technical problems in the prior art that in the process of plant monitoring, a plurality of monitoring devices are used for monitoring respectively, and each monitoring device works independently, resulting in increase in the cost, and inconvenience of adjustment and control; due to the single function, extension power connectors in the market cannot cooperate with each monitoring device, resulting in that the requirements for use cannot be met, and thus affecting the efficiency of plant monitoring.

In order to achieve the above purposes, an embodiment of the present invention provides a smart plant monitoring power connector, including an power connector, the power connector being used for accessing an external power supply, the power connector being further used for being connected to environment monitoring devices and supplying power to each of the environment monitoring devices, and the environment monitoring device being used for monitoring current environment information, further including:
a sensor interface circuit, the sensor interface circuit being used for connecting the environment monitoring device; and
a communication control circuit, the communication control circuit being connected to the sensor interface circuit, and the communication control circuit being used for acquiring, via the sensor interface circuit, the current environment information monitored by the environment monitoring device;
the communication control circuit being further used for performing information interaction with an intelligent communication terminal so as to send the acquired current environment information to the intelligent communication terminal;
the communication control circuit being further used for, after receiving environment adjustment information sent by the intelligent communication terminal, generating environment control information according to the environment adjustment information, and sending the environment control information to each of the environment monitoring devices via the sensor interface circuit, and the environment control information being used for adjusting and controlling each of the environment monitoring devices.

Optionally, the sensor interface circuit includes a sensor identifying end, a sensor information receiving end and a sensor control end; the sensor identifying end, the sensor information receiving end and the sensor control end being all connected to the communication control circuit, and the sensor identifying end, the sensor information receiving end and the sensor control end being further all used for being connected to the environment monitoring device; after connecting the environment monitoring device to the sensor identifying end and the sensor control end, the communication control circuit identifying a sensor category of the connected environment monitoring device according to the sensor identifying end; the communication control circuit acquiring the current environment information monitored by the connected environment monitoring device according to the sensor information receiving end; the communication control circuit being further used for sending the environment control information to the environmental monitoring device via the sensor control end.

Optionally, a power metering circuit is further included, the power metering circuit being used for being connected to the external power supply, the power metering circuit being further connected to the communication control circuit, the communication control circuit being further used for sending a power usage query signal to the power metering circuit, and after receiving the power usage query signal, the power metering circuit generating actual power usage information according to the acquired actual electric energy input by the external power supply, and sending the actual power usage information to the communication control circuit.

After receiving the actual power usage information, the communication control circuit sends the actual power usage information to the intelligent communication terminal, so that the intelligent communication terminal displays the actual power usage information.

Optionally, a zero-crossing detection circuit and a power supply switch control circuit are further included, the zero-crossing detection circuit being connected to the communication control circuit and used for detecting the zero-point voltage of the external power supply; the power supply switch control circuit being connected to both the communication control circuit and the power connector, the communication control circuit being further used for generating a power supply turn-on signal after acquiring the zero-point voltage detected by the zero-crossing detection circuit and sending the power supply turn-on signal to the power supply switch control circuit so that the power supply switch control circuit controls the power connector to be turned on at the zero-point voltage according to the power supply turn-on signal.

Optionally, a key start-stop circuit is further included, the key start-stop circuit being connected to the communication control circuit, the communication control circuit, when the key start-stop circuit is triggered, generating a power connector control signal after acquiring a power connector start-stop signal triggering the key start-stop circuit, and sending the power connector control signal to the power supply switch control circuit, and the power supply switch control circuit controlling the power connector to be turned on at the zero-point voltage according to the power connector control signal.

One or more of the above technical solutions of the smart plant monitoring power connector provided by the embodiment of the present invention at least have one of the technical effects as follows.

Compared with a common extension power connector in the prior art, the smart plant monitoring power connector according to the present invention further integrates a sensor interface circuit for connecting environment monitoring devices, so that each environment monitoring device can be connected to the sensor interface circuit in a unified manner, in this way, it is no longer necessary to use each monitoring device to perform separate monitoring respectively, and all the monitoring devices separately working are connected in series via the smart plant monitoring power connector, and the current environment information monitored during the plant production process is uniformly and centrally processed via the disposed communication control circuit, which can be achieved only by using the smart plant monitoring power connector as a master control device. The problem in the prior art that each monitoring device has a control device, resulting in a high production cost is solved. An intelligent communication terminal, such a mobile phone, can perform information interaction with the smart plant monitoring power connector, so that a user can send environment adjustment information through the intelligent communication terminal, and all the monitoring devices connected to the smart plant monitoring power connector are adjusted and controlled with the smart plant monitoring power connector as an information receiving and transferring point, so as to achieve uniform adjustment and control on the process of plant growth. In addition, the smart plant monitoring power connector is used as the master control device for the first time. Since power supply is essential in the plant monitoring process, by combining the power supply and control, there is no need to separately set the power supply, the convenience in the plant growth monitoring process is greatly improved, so as to meet the user's use requirements, which improves the plant monitoring efficiency.

In order to achieve the above purposes, an embodiment of the present invention further provides a method for controlling plant monitoring, being carried out on the basis of the above smart plant monitoring power connector, and including the following steps:
step S100: identifying, by the communication control circuit, a sensor category of a connected environment monitoring device according to a sensor identifying end in the sensor interface circuit;
step S200: acquiring, by the communication control circuit, current environment information monitored by the connected environment monitoring device according to a sensor information receiving end in the sensor interface circuit; and
step S300: sending, by the communication control circuit, the current environment information to an intelligent communication terminal so that the intelligent communication terminal displays the current environment information.

Optionally, the method for controlling plant monitoring further includes the following steps:
step S410: after sending, by the intelligent communication terminal, environment adjustment information to the communication control circuit, generating, by the communication control circuit, environment control information according to the environment adjustment information; and
step S420: sending, by the communication control circuit, the environment control information to each of the environment monitoring devices via the sensor interface circuit, the environment control information being used for adjusting and controlling each of the environment monitoring devices.

Optionally, the method for controlling plant monitoring further includes the following steps:
step S510: after acquiring a zero-point voltage detected by a zero-crossing detection circuit in the smart plant monitoring power connector, generating, by the communication control circuit, a power supply turn-on signal according to the zero-point voltage;
step S520: sending, by the communication control circuit, the power supply turn-on signal to a power supply switch control circuit in the smart plant monitoring power connector; and
step S530: controlling, by the power supply switch control circuit, the power connector to be turned on at the zero-point voltage according to the power supply turn-on signal.

Optionally, the method for controlling plant monitoring further includes the following steps:
step S610: sending, by the communication control circuit, a power usage query signal to a power metering circuit in the smart plant monitoring power connector;
step S620: after receiving the power usage query signal, generating, by the power metering circuit, actual power usage information according to the acquired actual electric energy input by the external power supply, and sending the actual power usage information to the communication control circuit; and
step S630: after receiving the actual power usage information, sending, by the communication control circuit, the actual power usage information to the intelligent communication terminal, so that the intelligent communication terminal displays the actual power usage information.

In order to achieve the above purposes, an embodiment of the present invention further provides a method for controlling plant monitoring, being carried out on the basis of the above smart plant monitoring power connector and an intelligent control terminal, and including the following steps:
step S710: identifying, by the communication control circuit, a sensor category of a connected environment monitoring device according to a sensor identifying end in the sensor interface circuit;
step S720; acquiring, by the communication control circuit, current environment information monitored by the connected environment monitoring device according to a sensor information receiving end in the sensor interface circuit;
step S730: sending, by the communication control circuit, the current environment information to the intelligent communication terminal; and
step S740: displaying the current environment information by the intelligent communication terminal.

One or more of the above technical solutions of the method for controlling plant monitoring provided by the embodiment of the present invention at least have one of the technical effects as follows.

According to the method for controlling plant monitoring of the present invention, firstly, identifying, by the communication control circuit, a sensor category of a connected environment monitoring device according to a sensor identifying end in the sensor interface circuit; then, acquiring, by the communication control circuit, current environment information monitored by the connected environment monitoring device according to a sensor information receiving end in the sensor interface circuit; next, sending, by the communication control circuit, the current environment information to an intelligent communication terminal so that the intelligent communication terminal displays the current environment information and then it is also no longer necessary to use each monitoring device to perform separate monitoring respectively, and all the monitoring devices separately working are connected in series via the smart plant monitoring power connector, and the current environment information monitored during the plant production process is uniformly and centrally processed via the disposed communication control circuit. The smart plant monitoring power connector is used as a master control device for the first time. Since power supply is essential in the plant monitoring process, by combining the power supply and control, there is no need to separately set the power supply, the convenience in the plant growth monitoring process is greatly improved, so as to meet the user's use requirements, which improves the plant monitoring efficiency.

### BRIEF DESCRIPTION OF THE DRAWINGS

To describe the technical solutions in embodiments of the present invention more clearly, the following briefly describes the accompanying drawings required for describing the embodiments or the prior art. Apparently, the accompanying drawings in the following description show only some embodiments of the present invention, and a person of ordinary skill in the art may still derive other accompanying drawings from the accompanying drawings without creative efforts.

FIG. 1 is a schematic view of an overall structure of a smart plant monitoring power connector provided by an embodiment of the present invention;

FIG. 2 is a schematic flowchart of a method for controlling plant monitoring provided by an embodiment of the present invention;

FIG. 3 is a schematic flowchart for adjusting and controlling each environment monitoring device provided by an embodiment of the present invention;

FIG. 4 is a schematic flowchart for turning on an power connector provided by an embodiment of the present invention;

FIG. 5 is a schematic flowchart for displaying actual power usage information provided by an embodiment of the present invention; and

FIG. 6 is a schematic flowchart for an intelligent communication terminal to display current environment information provided by an embodiment of the present invention.

### LIST OF REFERENCE NUMERALS IN THE DRAWINGS

100, power connector; 200, environment monitoring device; 300, sensor interface circuit; 400, communication control circuit; 500, intelligent communication terminal; 600, power metering circuit; 710, zero-crossing detection circuit; 720, power supply switch control circuit; 800, key start-stop circuit.

### DETAILED DESCRIPTION OF THE INVENTION

Embodiments of the present invention will be described in detail below, and examples of the embodiments are illustrated in the accompanying drawings, wherein same or similar reference numerals refer to the same or similar elements or elements with the same or similar function throughout the description. The embodiments described below with reference to the accompanying drawings are exemplary and are intended to explain embodiments of the present invention and are not to be construed as limiting the present invention.

In the description of the embodiment of the present invention, it should be understood that, the orientation or positional relationships indicated by terms “length,” “width,” “upper,” “lower,” “front,” “rear,” “left;” “right.” “vertical.” “horizontal,” “top,” “bottom,” “inner,” “outer,” etc. are based on the orientation or positional relationships shown in the drawings and are only for facilitating the description of the embodiment of the present invention and simplifying the description, rather than indicating or implying that the apparatus or element referred to must have a particular orientation or be constructed and operated in a particular orientation, and therefore will not be interpreted as limiting the present invention.

In addition, the terms “first” and “second” are used for descriptive purposes only and are not to be construed as indicating or implying relative importance or implicitly indicating the number of technical features indicated. Therefore, a feature restricted by “first” or “second” may explicitly indicate or implicitly include one or more such features. In the description of the embodiment of the present invention, “a plurality of” means two or two or more, unless it is specifically defined otherwise.

In the embodiment of the present invention, unless otherwise explicitly specified and defined, terms such as “mounted”, “connected”, “connection”, and “fixed” should be understood in a broad sense. For example, the connection may be a fixed connection, a detachable connection, or an integral connection; the connection may be a mechanical connection or an electrical connection; the connection may be directly connected or indirectly connected through an intermediate medium, and may be the communication between two elements or the interaction relationship between two elements. A person of ordinary skill in the art may understand the specific meanings of the foregoing terms in the embodiment of the present invention according to specific situations.

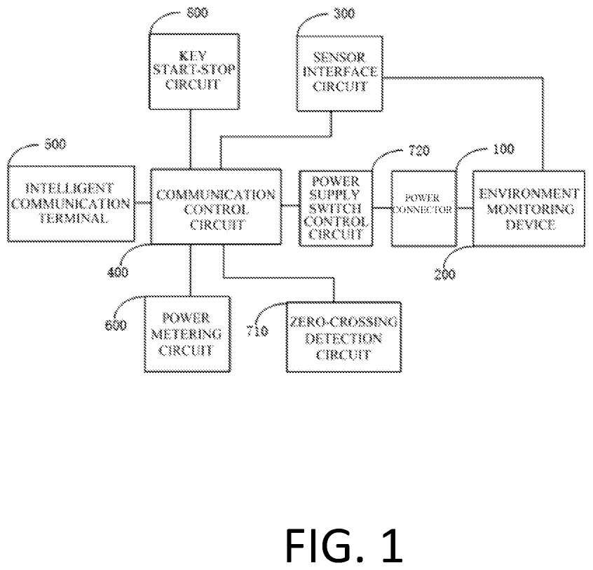

In an embodiment of the present invention, as shown in FIG. 1, providing a smart plant monitoring power connector, including an power connector 100, the power connector 100 being used for accessing an external power supply, the power connector 100 being further used for being connected to environment monitoring devices 200 and supplying power to each of the environment monitoring devices 200, and the environment monitoring device 200 being used for monitoring current environment information.

The environment monitoring device 200 includes, but is not limited to, various types of sensors, such as a temperature and humidity sensor, a dimmer, a heating pad, a carbon dioxide detection sensor, a camera, etc. so as to realize information acquisition of temperature, humidity, carbon dioxide concentration, an image, etc. based on the environment monitoring device 200, and also realize control over dimming and the heating pad.

The smart plant monitoring power connector further includes a sensor interface circuit 300 and a communication control circuit 400, the sensor interface circuit 300 being used for connecting the environment monitoring device 200; the communication control circuit 400 being connected to the sensor interface circuit 300, and the communication control circuit 400 being used for acquiring, via the sensor interface circuit 300, the current environment information monitored by the environment monitoring device 200.

The communication control circuit 400 is further used for performing information interaction with an intelligent communication terminal 500 so as to send the acquired current environment information to the intelligent communication terminal 500. The intelligent communication terminal 500 includes, but is not limited to, electronic devices such as mobile phones, tablet computers, and other computers, as long as information regulation and control with the communication control circuit 400 can be realized.

Further, the communication mode between the communication control circuit 400 and the intelligent communication terminal 500 includes, but is not limited to, Bluetooth and WiFi.

The communication control circuit 400 is further used for, after receiving environment adjustment information sent by the intelligent communication terminal 500, generating environment control information according to the environment adjustment information, and sending the environment control information to each of the environment monitoring devices 200 via the sensor interface circuit 300, and the environment control information being used for adjusting and controlling each of the environment monitoring devices 200. The environment adjustment information is a specific sensor parameter set on the intelligent communication terminal 500 by a user, such as “increasing illumination”, then the communication control circuit 400 generates environment control information according to the environment adjustment information, the environment control information is instruction information corresponding to the environment adjustment information, and the environment control information is used for adjusting and controlling each of the environment monitoring device 200, and enabling each of the environment monitoring devices 200 to perform an action matching with the environment adjustment information.

Compared with a common extension power connector in the prior art, the smart plant monitoring power connector according to the present invention further integrates a sensor interface circuit 300 for connecting environment monitoring devices 200, so that each environment monitoring device 200 can be connected to the sensor interface circuit 300 in a unified manner, in this way, it is no longer necessary to use each monitoring device to perform separate monitoring respectively, and all the monitoring devices separately working are connected in series via the smart plant monitoring power connector, and the current environment information monitored during the plant production process is uniformly and centrally processed via the disposed communication control circuit 400, which can be achieved only by using the smart plant monitoring power connector as a master control device. The problem in the prior art that each monitoring device has a control device, resulting in a high production cost is solved. An intelligent communication terminal 500, such a mobile phone, can perform information interaction with the smart plant monitoring power connector, so that a user can send environment adjustment information through the intelligent communication terminal 500, and all the monitoring devices connected to the smart plant monitoring power connector are adjusted and controlled with the smart plant monitoring power connector as an information receiving and transferring point, so as to achieve uniform adjustment and control on the process of plant growth. In addition, the smart plant monitoring power connector is used as the master control device for the first time. Since power supply is essential in the plant monitoring process, by combining the power supply and control, there is no need to separately set the power supply, the convenience in the plant growth monitoring process is greatly improved, so as to meet the user's use requirements, which improves the plant monitoring efficiency.

In another embodiment of the present invention, the sensor interface circuit 300 includes a sensor identifying end, a sensor information receiving end, and a sensor control end.

The sensor identifying end, the sensor information receiving end and the sensor control end are all connected to the communication control circuit 400, and the sensor identifying end, the sensor information receiving end and the sensor control end are further all used for being connected to the environment monitoring device 200. After connecting the environment monitoring device 200 to the sensor identifying end and the sensor control end, the communication control circuit 400 identifies a sensor category of the connected environment monitoring device 200 according to the sensor identifying end. The communication control circuit 400 acquires the current environment information monitored by the connected environment monitoring device 200 according to the sensor information receiving end. The communication control circuit 400 is further used for sending the environment control information to the environmental monitoring device 200 via the sensor control end.

Further, before the various types of environment monitoring devices 200 are identified based on the sensor identifying end, the frequencies of the environment monitoring devices 200 are identified in advance and stored as specific frequencies corresponding to the environment monitoring devices 200, so that each of the environment monitoring devices 200 has a specific frequency. When each of the environment monitoring devices 200 is connected to the sensor interface circuit 300, the communication control circuit 400 identifies the sensor category of the connected environment monitoring device 200 according to the sensor identifying end based on the specific frequency, so that the communication control circuit 400 acquires the specific category of the connected environment monitoring device 200; and after the communication control circuit 400 sends the sensor category to the intelligent communication terminal 500, the corresponding environment monitoring device 200 is displayed on the intelligent communication terminal 500, and each of the environment monitoring devices 200 is visually displayed so as to facilitate individually or uniformly adjusting and controlling each of the environment monitoring devices 200 by the user.

In another embodiment of the present invention, a tag may be set in advance for each of the environment monitoring devices 200, such that each of the environment monitoring devices 200 correspondingly has a particular tag. When each environment monitoring device 200 is connected to the sensor interface circuit 300, the communication control circuit 400 identifies the sensor category of the connected environment monitoring device 200 on the basis of the particular tag according to the sensor identifying end.

In another embodiment of the present invention, as shown in FIG. 1, the smart plant monitoring power connector further includes a power metering circuit 600, the power metering circuit 600 being used for being connected to the external power supply, the power metering circuit 600 being further connected to the communication control circuit 400, the communication control circuit 400 being further used for sending a power usage query signal to the power metering circuit 600, and after receiving the power usage query signal, the power metering circuit 600 generating actual power usage information according to the acquired actual electric energy input by the external power supply, and sending the actual power usage information to the communication control circuit 400.

After receiving the actual power usage information, the communication control circuit 400 sends the actual power usage information to the intelligent communication terminal 500, so that the intelligent communication terminal 500 displays the actual power usage information. In this way, by disposing of the power metering circuit 600, it is realized that a user can timely know power consumption information about various types of environment monitoring devices 200, thereby achieving regulation and control in time.

In another embodiment of the present invention, as shown in FIG. 1, the smart plant monitoring power connector further includes a zero-crossing detection circuit 710 and a power supply switch control circuit 720, the zero-crossing detection circuit 710 being connected to the communication control circuit 400 and used for detecting the zero-point voltage of the external power supply; the power supply switch control circuit 720 being connected to both the communication control circuit 400 and the power connector 100, the communication control circuit 400 being further used for generating a power supply turn-on signal after acquiring the zero-point voltage detected by the zero-crossing detection circuit 710 and sending the power supply turn-on signal to the power supply switch control circuit 720 so that the power supply switch control circuit 720 controls the power connector 100 to be turned on at the zero-point voltage according to the power supply turn-on signal.

In this embodiment, a plurality of relays (not shown in the figure) are included in the power supply switch control circuit 720, and each of the relays is connected to one of plug points in the power connector 100. When one relay is controlled to be closed, the plug point corresponding to the relay is powered on, so that the plug point can be used to supply power for an external device.

Furthermore, in this embodiment, since the external power supply is a power supply with an alternating current, taking the mains supply as an example, during the conversion of a positive waveform and a negative waveform, there is a 0 voltage, namely, the zero-point voltage in the present application, the power connector 100 is turned on at the zero-point voltage, specifically, the relay is closed at the zero-point voltage, so as to minimize the damage to the relay. As compared with the problem in the prior art that sparks are easily generated and damage to the relay is easily caused when the relay is controlled to be closed when being powered on, the present invention is based on the arrangement of the zero-crossing detection circuit 710, the safety in the control process of the relay is greatly improved, and the service life of the relay is also greatly prolonged, thereby indirectly prolonging the service life of the smart plant monitoring power connector.

In another embodiment of the present invention, as shown in FIG. 1, the smart plant monitoring power connector further includes a key start-stop circuit 800, the key start-stop circuit 800 being connected to the communication control circuit 400, the communication control circuit 400, when the key start-stop circuit 800 is triggered, generating a power connector control signal after acquiring a power connector start-stop signal triggering the key start-stop circuit 800, and sending the power connector control signal to the power supply switch control circuit 720, and the power supply switch control circuit 720 controlling the power connector 100 to be turned on at the zero-point voltage according to the power connector control signal.

In this embodiment, the key start-stop circuit 800 includes a plurality of keys (not shown in the figure), and the convenience in use is improved by triggering each of the keys to set whether to supply power for the plug point in the power connector 100.

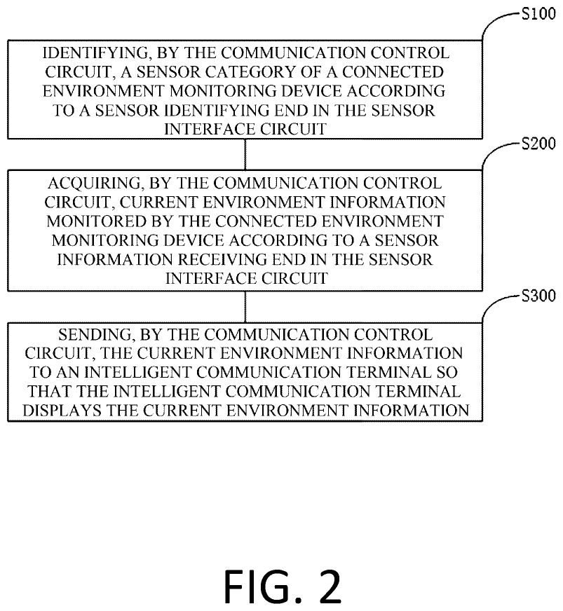

In another embodiment of the present invention, as shown in FIG. 2, the present invention further provides a method for controlling plant monitoring, being carried out on the basis of the above smart plant monitoring power connector, and including the following steps:
step S100: identifying, by the communication control circuit 400, a sensor category of a connected environment monitoring device 200 according to a sensor identifying end in the sensor interface circuit 300;
step S200: acquiring, by the communication control circuit 400, current environment information monitored by the connected environment monitoring device 200 according to a sensor information receiving end in the sensor interface circuit 300; and
step S300: sending, by the communication control circuit 400, the current environment information to an intelligent communication terminal 500 so that the intelligent communication terminal 500 displays the current environment information.

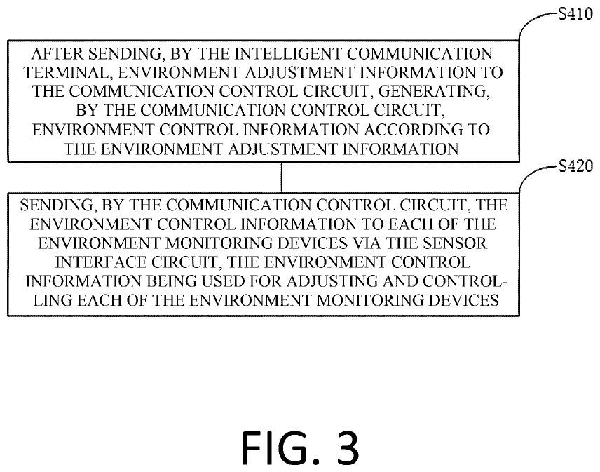

In another embodiment of the present invention, as shown in FIG. 3, the method for controlling plant monitoring further includes the following steps:
step S410: after sending, by the intelligent communication terminal 500, environment adjustment information to the communication control circuit 400, generating, by the communication control circuit 400, environment control information according to the environment adjustment information; and
step S420: sending, by the communication control circuit 400, the environment control information to each of the environment monitoring devices 200 via the sensor interface circuit 300, the environment control information being used for adjusting and controlling each of the environment monitoring devices 200.

According to the method for controlling plant monitoring of the present invention, firstly, identifying, by the communication control circuit 400, a sensor category of a connected environment monitoring device 200 according to a sensor identifying end in the sensor interface circuit 300; then, acquiring, by the communication control circuit 400, current environment information monitored by the connected environment monitoring device 200 according to a sensor information receiving end in the sensor interface circuit 300; next, sending, by the communication control circuit 400, the current environment information to an intelligent communication terminal 500 so that the intelligent communication terminal 500 displays the current environment information and then it is also no longer necessary to use each monitoring device to perform separate monitoring respectively, and all the monitoring devices separately working are connected in series via the smart plant monitoring power connector, and the current environment information monitored during the plant production process is uniformly and centrally processed via the disposed communication control circuit 400. The smart plant monitoring power connector is used as a master control device for the first time. Since power supply is essential in the plant monitoring process, by combining the power supply and control, there is no need to separately set the power supply, the convenience in the plant growth monitoring process is greatly improved, so as to meet the user's use requirements, which improves the plant monitoring efficiency.

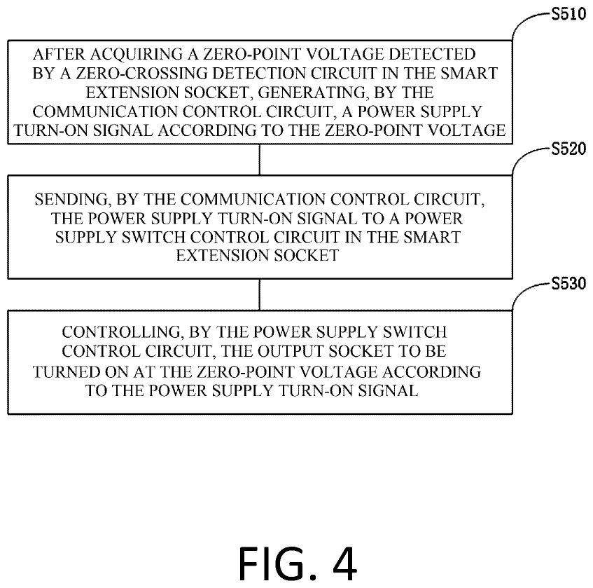

In another embodiment of the present invention, as shown in FIG. 4, the method for controlling plant monitoring further includes the following steps:
step S510: after acquiring a zero-point voltage detected by a zero-crossing detection circuit 710 in the smart plant monitoring power connector, generating, by the communication control circuit 400, a power supply turn-on signal according to the zero-point voltage;
step S520: sending, by the communication control circuit 400, the power supply turn-on signal to a power supply switch control circuit 720 in the smart plant monitoring power connector; and
step S530: controlling, by the power supply switch control circuit 720, the power connector 100 to be turned on at the zero-point voltage according to the power supply turn-on signal 100.

Further, in the present invention, the power supply switch control circuit 720 controls the power connector 100 to be tuned on at the zero-point voltage according to the power supply turn-on signal, so that the problem in the prior art that sparks are easily generated and damage to the relay is easily caused when the relay is controlled to be closed when being powered on is solved, the safety in the control process of the relay is greatly improved, and the service life of the relay is also greatly prolonged, thereby indirectly prolonging the service life of the smart plant monitoring power connector.

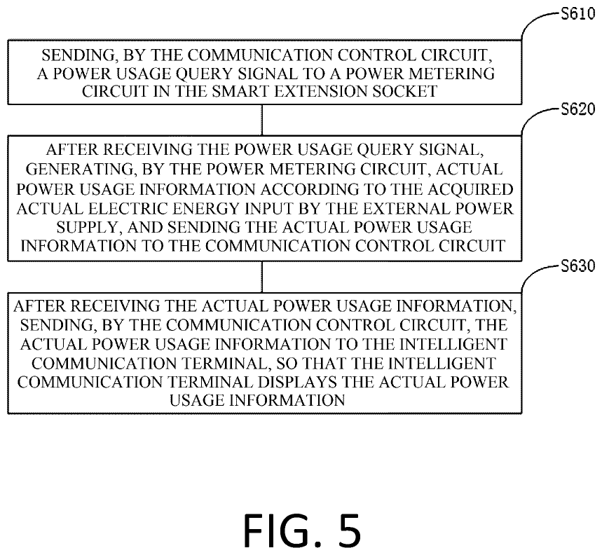

In another embodiment of the present invention, as shown in FIG. 5, the method for controlling plant monitoring further includes the following steps:
step S610: sending, by the communication control circuit 400, a power usage query signal to a power metering circuit 600 in the smart plant monitoring power connector;
step S620: after receiving the power usage query signal, generating, by the power metering circuit 600, actual power usage information according to the acquired actual electric energy input by the external power supply, and sending the actual power usage information to the communication control circuit 400; and
step S630: after receiving the actual power usage information, sending, by the communication control circuit 400, the actual power usage information to the intelligent communication terminal 500, so that the intelligent communication terminal 500 displays the actual power usage information.

Furthermore, the present invention firstly generates, via the power metering circuit 600, the actual power usage information according to the acquired actual electric energy input by the external power supply after receiving the power usage query signal, and sends the actual power usage information to the communication control circuit 400, and then enables the communication control circuit 400, after receiving the actual power usage information, to send the actual power usage information to the intelligent communication terminal 500, so that the intelligent communication terminal 500 displays the actual power usage information, achieving on-demand count and display of power.

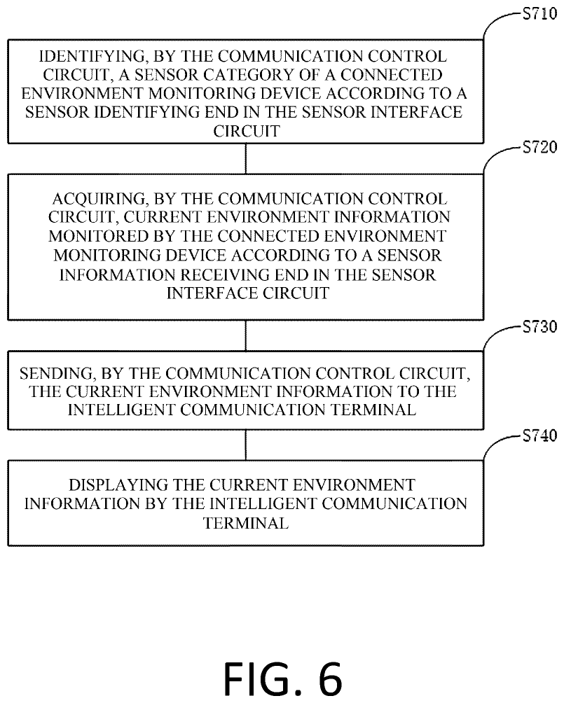

In another embodiment of the present invention, as shown in FIG. 6, the present invention further provides a method for controlling plant monitoring, being carried out on the basis of the above smart plant monitoring power connector and an intelligent control terminal, and including the following steps:
step S710: identifying, by the communication control circuit 400, a sensor category of a connected environment monitoring device 200 according to a sensor identifying end in the sensor interface circuit 300;
step S720: acquiring, by the communication control circuit 400, current environment information monitored by the connected environment monitoring device 200 according to a sensor information receiving end in the sensor interface circuit 300;
step S730: sending, by the communication control circuit 400, the current environment information to the intelligent communication terminal 500; and
step S740: displaying the current environment information by the intelligent communication terminal 500.

The above description is only preferred embodiments of the present invention and not intended to limit the present invention. Any modification, equivalent replacement, or improvement made within the spirit and principle of the present invention shall fall within the protection scope of the present invention.

1. A smart plant monitoring power connector, comprising
an power connector with access to an external power supply, the power connector coupled to environment monitoring devices and supplying power to each of the environment monitoring devices, and the environment monitoring device monitors current environment information;
a sensor interface circuit coupled to the environment monitoring device;
a communication control circuit coupled to the sensor interface circuit;
wherein the communication control circuit, via the sensor interface circuit, acquires the current environment information obtained by the environment monitoring device;
the communication control circuit performs an information interaction with an intelligent communication terminal and sends the acquired current environment information to the intelligent communication terminal; and
the communication control circuit further generates an environment control information according to an environment adjustment information received from the intelligent communication terminal, and sends the environment control information to each of the environment monitoring devices via the sensor interface circuit, wherein the environment control information adjusts and controls each of the environment monitoring devices.

2. The smart plant monitoring power connector according to claim 1, wherein the sensor interface circuit comprises
a sensor identifying end, a sensor information receiving end, and a sensor control end;
wherein the sensor identifying end, the sensor information receiving end, and the sensor control end are all coupled to the communication control circuit; and
the sensor identifying end, the sensor information receiving end, and the sensor control end are also coupled to the environment monitoring device;
the communication control circuit identifies a sensor category of the connected environment monitoring device according to the sensor identifying end after connecting the environment monitoring device to the sensor identifying end and the sensor control end, acquires the current environment information monitored by the connected environment monitoring device according to the sensor information receiving end, and sends the environment control information to the environmental monitoring device via the sensor control end.

3. The smart plant monitoring power connector according to claim 1, further comprising
a power metering circuit coupled to the external power supply;
the power metering circuit being further coupled to the communication control circuit;
wherein the communication control circuit sends a power usage query signal to the power metering circuit;
the power metering circuit generates an actual power usage information, after receiving the power usage query signal, according to the acquired actual electric energy input by the external power supply, and sends the actual power usage information to the communication control circuit;
the communication control circuit sends the actual power usage information to the intelligent communication terminal after receiving the actual power usage information; and
the intelligent communication terminal displays the actual power usage information.

4. The smart plant monitoring power connector according to claim 1, further comprising
a zero-crossing detection circuit and a power supply switch control circuit;
the zero-crossing detection circuit coupled to the communication control circuit and detects the zero-point voltage of the external power supply;
the power supply switch control circuit coupled to both the communication control circuit and the power connector;
the communication control circuit generates a power supply turn-on signal after acquiring the zero-point voltage detected by the zero-crossing detection circuit and sends the power supply turn-on signal to the power supply switch control circuit so that the power supply switch control circuit controls the power connector to be turned on at the zero-point voltage according to the power supply turn-on signal.

5. The smart plant monitoring power connector according to claim 4, further comprising
a key start-stop circuit coupled to the communication control circuit;
the communication control circuit, when the key start-stop circuit is triggered, generates a power connector control signal after acquiring a power connector start-stop signal triggers the key start-stop circuit, and sends the power connector control signal to the power supply switch control circuit; and
the power supply switch control circuit controlling the power connector to be turned on at the zero-point voltage according to the power connector control signal.

6. A method for controlling plant monitoring using a smart plant monitoring power connector and comprising the following steps:
step S100: identifying, by the communication control circuit, a sensor category of a connected environment monitoring device according to a sensor identifying end in the sensor interface circuit;
step S200: acquiring, by the communication control circuit, current environment information monitored by the connected environment monitoring device according to a sensor information receiving end in the sensor interface circuit; and
step S300: sending, by the communication control circuit, the current environment information to an intelligent communication terminal so that the intelligent communication terminal displays the current environment information.

7. The method for controlling plant monitoring according to claim 6, further comprising the following steps:
step S410: after sending, by the intelligent communication terminal, an environment adjustment information to the communication control circuit, generating, by the communication control circuit, an environment control information according to the environment adjustment information; and
step S420: sending, by the communication control circuit, the environment control information to each of the environment monitoring devices via the sensor interface circuit, the environment control information being used for adjusting and controlling each of the environment monitoring devices.

8. The method for controlling plant monitoring according to claim 6, further comprising the following steps:
step S510: after acquiring a zero-point voltage detected by a zero-crossing detection circuit in the smart plant monitoring power connector, generating, by the communication control circuit, a power supply turn-on signal according to the zero-point voltage;
step S520: sending, by the communication control circuit, the power supply turn-on signal to a power supply switch control circuit in the smart plant monitoring power connector; and
step S530; controlling, by the power supply switch control circuit, the power connector to be turned on at the zero-point voltage according to the power supply turn-on signal.

9. The method for controlling plant monitoring according to claim 6, further comprising the following steps:
step S610: sending, by the communication control circuit, a power usage query signal to a power metering circuit in the smart plant monitoring power connector;
step S620: after receiving the power usage query signal, generating, by the power metering circuit, actual power usage information according to the acquired actual electric energy input by the external power supply, and sending the actual power usage information to the communication control circuit; and
step S630: after receiving the actual power usage information, sending, by the communication control circuit, the actual power usage information to the intelligent communication terminal, so that the intelligent communication terminal displays the actual power usage information.

10. A method for controlling plant monitoring using a smart plant monitoring power connector and an intelligent control terminal, and comprising the following steps:
step S710: identifying, by the communication control circuit, a sensor category of a connected environment monitoring device according to a sensor identifying end in the sensor interface circuit;
step S720: acquiring, by the communication control circuit, current environment information monitored by the connected environment monitoring device according to a sensor information receiving end in the sensor interface circuit;
step S730: sending, by the communication control circuit, the current environment information to the intelligent communication terminal; and
step S740: displaying the current environment information by the intelligent communication terminal.
